(19) United States
(12) Patent Application Publication
(10) Pub. No.: US 2025/0362591 A1
(43) Pub. Date: Nov. 27, 2025

(54) INSPECTION DEVICE WITH METASURFACE POLARIZATION BEAM SPLITTER

(71) Applicant: CORNING INCORPORATED, CORNING, NY (US)

(72) Inventors: Paulo Clovis Dainese, JR., Painted Post, NY (US); Abhinav Nishant, Painted Post, NY (US)

(21) Appl. No.: 19/202,622

(22) Filed: May 8, 2025

Related U.S. Application Data
(60) Provisional application No. 63/650,600, filed on May 22, 2024.

(51) Int. Cl. G03F 1/84; G01N 21/88; G01N 21/956

(52) U.S. Cl. CPC G03F 1/84; G01N 21/8806; G01N 21/956; G01N 2021/8848; G01N 2021/95676

(57) ABSTRACT

An inspection device comprising: a quarter wave plate; and a metasurface based polarizing beam splitter situated adjacent to the quarter wave plate. In some embodiments the inspection device includes an optical objective lens a zoom lens situated between the object plane and the quarter wave plate. A photo mask may be situated at the object plane of the inspection device.

### CROSS-REFERENCE TO RELATED APPLICATIONS

This application claims the benefit of priority under 35 U.S.C. § 119 of U.S. Provisional Application Ser. No. 63/650,600 filed on May 22, 2024, the content of which is relied upon and incorporated herein by reference in its entirety.

### FIELD

The disclosure relates generally to a metasurface based polarizing beam splitters, and more particularly metasurface based polarizing beam splitters for photomask inspection in the deep ultraviolet wavelength region and inspection devices comprising polarization metasurface based polarizing beam splitter.

### BACKGROUND

Reticle inspection tools are an essential component of the semiconductor lithography industry wherein a deep ultraviolet (λ=266 nm) light source is used to inspect photomasks (also referred as reticles herein) for inclusion of defects printed during the lithography process. Any defect printed on the photomask can potentially impact of millions of semiconductor chips made by using the defective photomask, drastically reducing the yield and resulting in financial loss.

Photomask inspection devices currently utilize circularly polarized light that is incident on the photomask and analyze reflected light from the photomask, which is also circularly polarized, to locate defects in photomasks. When the reflected light enters the inspection device, the reflected beam needs to be diverted, so as not to propagate toward the source, but instead to a sensor or detection system for analysis. Circularly polarized light reflected from the mask enters a waveplate that converts it to a linearly polarized light, and this linearly polarized light then passed through the beam splitting prism before impinging onto a detector. It is noted that polarizing beam splitters that split circularly polarized light do not exist.

As the size of electronics (e.g., transistors) is shrinking, manufacturing process for electronics is becoming more complex, and it is becoming harder to identify smaller defects in the photomasks for such devices. The current inspection systems do not have enough sensitivity to detect minute/smaller defects in the photomasks. Better inspection systems are needed to detect small defects in a rapidly developing smaller size electronic circuitry. As the electronic circuitry becomes smaller, interaction of light with smaller parts becomes more challenging, and in some cases illuminating reticles with linearly polarized light can provide better resolution and advantages in defect detection. However, this requires using polarizing beam splitters in known detection devices, and this would reduce the detection efficiency by a factor of 3 or 4, i.e., to about 20 to 30%.

Accordingly, there is a need for new type of inspection mechanisms with improved signal to noise ratio (SNR) that are capable of inspecting small features or defects of miniaturized test objects.

No admission is made that any reference cited herein constitutes prior art. Applicant expressly reserves the right to challenge the accuracy and pertinency of any cited documents.

### SUMMARY

One embodiment of the disclosure relates to an inspection device comprising: (i) a quarter wave plate; and (ii) a metasurface based polarizing beam splitter situated adjacent to the quarter wave plate.

In some embodiments the inspection device includes an optical objective lens a zoom lens situated between the object plane and the quarter wave plate.

In some embodiments, the inspection device is a photomask inspection device and the photo mask is situated at the object plane of the inspection device.

Additional features and advantages will be set forth in the detailed description which follows, and in part will be readily apparent to those skilled in the art from the description or recognized by practicing the embodiments as described in the written description and claims hereof, as well as the appended drawings.

It is to be understood that both the foregoing general description and the following detailed description are merely exemplary, and are intended to provide an overview or framework to understand the nature and character of the claims.

The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is a schematic view of operation of one or more embodiments of the inspection device described;

FIG. 2 illustrates one embodiment of a library of metasurfaces using HfO₂ nanopillars;

FIG. 3 illustrates phase delay results produces by 600 nm tall pillars of one embodiment of a metasurface library utilized by an inspection device of FIG. 1;

FIG. 4 illustrates setup of the Pancharatnam Berry (PB) grating supercell and simulation setup;

FIG. 5 illustrates modeling results showing polarization and efficiency of PB grating utilized in one or more embodiments of the inspection device of FIG. 1;

FIG. 6 illustrates results showing polarization before and after exiting a quarter wave plate utilized in inspection device of FIG. 1; and

FIG. 7 illustrates modeling results of polarization evolution through the inspection the device as it passes through the various components, and the overall efficiency of one exemplary device (greater than 70%).

### DETAILED DESCRIPTION

Various embodiments will be further clarified by the following examples.

### Example 1

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

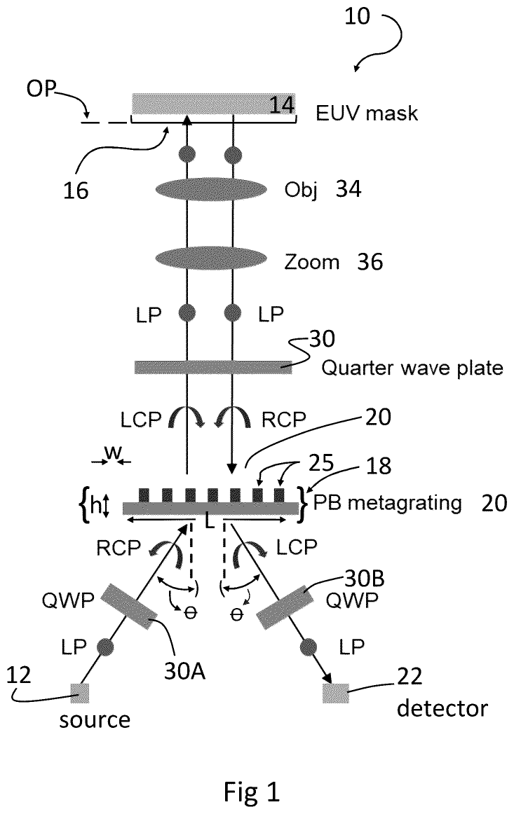

FIG. 1 illustrates schematically a polarization sensitive beam deflector device 10 that is suitable for use in for inspection of electronic components and or photomasks (reticles 14 while using deep UV light source (e.g., 193 nm or 266 nm) provided by the light source 12. In this embodiment, the light source 12 provides linearly polarized light to a quarter wave plate 31, which creates circularly polarized light impinging on the metasurface grating 20. The inspection device 10 further comprises a detector 22 capable of detecting the light at the wavelength providing by the light source. A quarter wave plate 30 B is located between the metasurface grating 20 and the detector 22, and converts circularly polarized light provided by the grating 20 to the linearly polarized light impinging by the detector 22.

More specifically, in this exemplary embodiment the inspection device 10 utilizes Pancharatnam Berry (PB) metasurface gratings 20 situated between the source 12 and the reticle (photomask) 14. Metasurfaces gratings 20 flip the polarization of circularly polarized light while deflecting the incoming light beam in +1 diffraction order. A quarter wave plate QWP 30 is then utilized to convert circular polarization of the light incident on thee QWP 30 into linearly polarized light that is incident on the reticle. In this embodiment, optical components 34, 36 (e.g., at least two lens components, for example an optical objective lens and a zoom lens) are utilized to focus the light propagating between the reticle 14 and the quarter wave plate 30. For example, the objective lens 34 is used focus (converge) the beam at the top surface of the reticle; and the zoom lens 36 provides a variable focal length, to focus the beam at the different areas (planes) of the photomask. The optical (lens) components 34 as 36 are situated between the quarter lens plate 30 and the plane P1 (object plane) where the component that is being tested (e.g., a photomask) is located. Each of the component 34, 36 may be comprise of multiple lens elements.

The two optical components 20, 30 in conjunction with one another separate he light incident on the reticle and light reflected by the reticle by angle 20, while the polarization also gets flipped. The device 10 thus enables linear polarized light to be incident on the photomask while allowing for maximum light utilization.

The input light from light source 12 is traveling at an angle θ=−7.55° (in glass) or θ=−11.36° (in air) with respect to the optical axis of the detection device 10. The polarization of the input light is right circularly polarized, also known as RCP. In this embodiment, the Pancharatnam Berry metasurface grating 20 rotates the polarization of the input light from RCP to left circularly polarized light, also known as LCP. The quarter wave plate (QWP) 30 can be made, for example, using birefringent materials such as quartz or LiBO₂. The QWP 30 has a slow axis SA and fast axis FA. The electric field traveling along the slow axis suffers a 90° phase retardance, also known as λ/4 optical path delay. The light exiting the QWP 30 is converted to linear polarization (LP) wherein the electric field is polarized at 45° with respect to the optical axis in which light is traveling. After passing through the QWP 30, the LP light is then incident on the test subject, for example EUV photomask (reticle 14). The reticle 14 is made of glass (e.g., silica) and may have an optional multilayer coating 16. In this embodiment coating 16 is a reflective coating.

The structures on the reticle 14 interact with the incident light, and approximately from 70% to just under 100% of the light incident on the reticle is reflected back. Thus, the overall efficiency of the inspection device 10 is preferably 70-100%, for example 75%, 80%, 85%, 90%, 95% or 99%. The reflected light which is linearly polarized then travels in the opposite direction and interacts with the quarter wave plate 30 which converts the polarization of the light from linear to circular polarization, known as RCP. The RCP light then interacts with the Pancharatnam Berry metasurface grating 20 which rotates the polarization to left circularly polarized (LCP) and gets deflected at +7.55° (in glass) or θ=+11.36° (in air) with respect to the optical axis. Therefore, the angular separation between the incoming beam and the reflected beam is 2θ, and in this embodiment the angle 2θ=15.1° (i.e., 2×7.55°) (in glass) or 2θ=22.73° (i.e., 2×11.36°) in air.

We have designed the inspection device 10 in three steps. Below we describe the design of each element and verify the device operation with the help of FDTD (fine difference time domain) simulations.

### Pancharatnam Berry Metasurface Grating 20

Pancharatnam Berry metasurface gratings are nanophotonic structures which operate by modifying the phase of the electromagnetic wave passing through the nano-sized pillars (nanopillars) 25. In this embodiment, Pancharatnam Berry metasurfaces are designed for bidirectional rotation of circularly polarized light. Pancharatnam Berry Metasurface grating 20 of this embodiment is structured such that the incident and reflected light are orthogonally polarized (LCP and RCP), and are separated in opposite angular directions. Use of high refractive index materials are preferable in order to achieve effective phase retardance from nanopillars. Such materials may be, for example, HfO₂ (n=2.08, k=0), or AlN (n=2.35, k=0).

### PB Grating Design Steps:

1. Choose materials for pillars, substrate, cladding, etc. with high transmission.
2. Build a metasurface library by sweeping over the rectangular pillar's width, length, and height. Choose unit cell size≤λ/2 (preferably, if too small then must be ≤λ). Alternatively, inverse design methods can be used to build elements of the library.
3. Calculate Transmission and Phase delay for x and y polarization, calculate phase retardance (Δϕ). Choose pillar dimension such that (Δϕ=π) and transmission is high.
4. Choose the number of pillars (N) to use for the supercell (L=N*uₓ where ux is the unit cell periodicity). The deflection angle of the grating depends on the length of the supercell and is determined by the following equation:

$$[ {n}_{g} sin ( {θ}_{defl} ) = \frac{λ}{L} ]$$

5. For PB grating to rotate RCP into LCP and vice versa, the geometric phase assigned to each pillar is given by:

$${ϕ}_{pillar} = \frac{2 π}{N}$$

6. Hence each pillar needs to be rotated by half of this value:

$$[ {θ}_{rot} = \frac{π}{N} ]$$

7. Check diffraction efficiency for RCP/LCP input and LCP/RCP output.

For example, in this exemplary embodiment, metasurfaces periodicity is chosen to be about λ/2, where λ is the operating wavelength of the inspection device 10. For the operating wavelength of about 266 nm (λ=266 nm) the desired periodicity will be about 130 nm to about 170 nm. Nanopillars 25 may have a lateral dimension(s) less than 75 nm, or even less than 50 nm and an aspect ratio R of (height to width) of 5 or greater, for example R=7, R=10, R=12, R=15, or therebetween.

More specifically, the lateral dimensions of the nanopillars 25 can be varied such that the linearly polarized EM wave in x and y directions experience different phase retardance as it passes through the pillars. For specific pillar dimensions, the nanopillar 25 acts as a halfwave plate and leads to a relative phase delay of x between the x and y linearly polarized light. When this same pillar interacts with circularly polarized light, it causes a phase delay of Φ which is twice the angular rotation (θ) of the pillars relative to the major axis of the structure (x axis in this case). Hence, this structure when used with circularly polarized light can provide a continuously variable phase based on nanopillars that differ only by rotation about the major axis. To convert LCP into RCP and vice-versa, we need to choose N number of pillars 25 which can sufficiently sample full 0 to 2π coverage. Preferably the nanopillar material(s) can be deposited using high quality thin film deposition techniques (PECVD, ALD) and can be etched while maintaining the high aspect ratio and vertical side walls.

The geometric phase assigned to each nanopillar 25 is given by:

$${ϕ}_{pillar} = \frac{2 π}{N} ,$$

and hence, the rotation of each pillar 25 should be π/N. The deflection angle of the grating is determined by the length of the supercell, such that

$${n}_{g} sin ( {θ}_{defl} ) = \frac{λ}{L} ;$$

where n_{g} is the refractive index of the medium in which light is launched, and L=N*uₓ where N is the number of pillars 25 used and uₓ is the periodicity of the unit cell. The periodicity of the unit cell on which each nanopillar 25 is located is chosen such that ux<λ, preferably ux=λ/2, where is the operating wavelength (e.g., 266 nm or 193 nm). The deflection angle of the grating depends on the length of the supercell as shown below:

$$[ {n}_{g} sin ( {θ}_{defl} ) = \frac{λ}{L} ]$$

In is exemplary embodiment, in order to create PB metagratings (metasurfaces), we have chosen Hafnium dioxide (HfO₂) as the material for nanopillars due to its high refractive index (n=2.08) and low absorption coefficient (k=0) at a 266 nm operating wavelength. Other materials which can be used are, for example, Aluminum Nitride (AlN), or Zirconia (ZrO₂) or Fused Silica. In this embodiment, Corning's high purity fused silica glass is used as the substrate material (n=1.50 at λ=266 nm).

We have performed finite difference time domain (FDTD) simulations in order to verify the operation of the PB gratings 20. The FDTD simulation process has three major steps:
(1) Meta-surface library generation, (2) Placement of a supercell (array of multiple unit sells containing nano-pillars 25) with length L (e.g., 9×150 nm, width=150 nm) containing a number of pillars (N) with L=N*uₓ, where ux is the unit cell periodicity, and (3) Verification of grating deflection and polarization rotation.

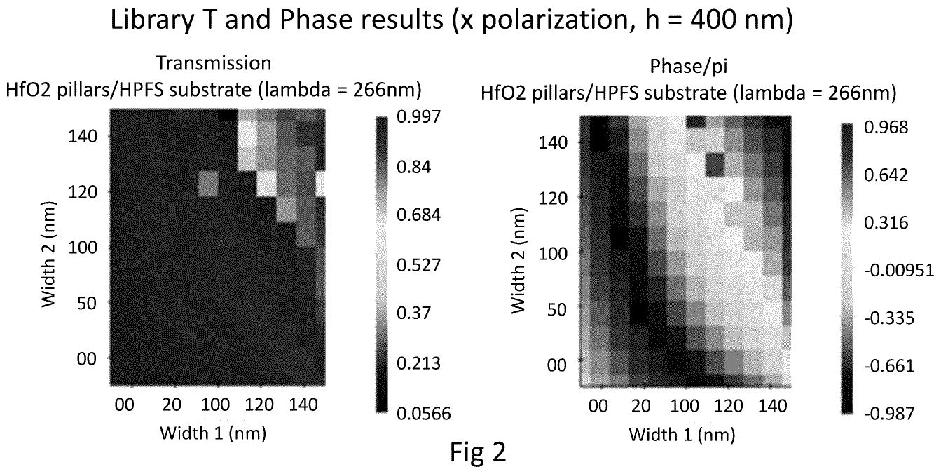

Meta surface library generation: In this embodiment, in order to create a metasurface library—comprising of HfO₂ nanopillars 25 on HPFS substrate, we chose a rectangular pillar 25 each having at height h=600 nm and vary the lateral width and length of the pillars. We launch linearly polarized light in x and y directions subsequently and monitor the transmission and phase of the outgoing light. Hence a 2D array of transmission (T) and phase delay is generated as a function of pillar widths W1, W2 (FIG. 2). M ore specifically, in this embodiment, the exemplary metasurface library was generated by performing finite difference time domain simulations (FDTD) utilizing simulation tools such as, for example, ANSYS Lumerical program, as an electromagnetic plane wave (light signal) travels through N nanopillars 25. In this exemplary embodiment, nanopillars 25 are HfO₂ nanopillars. The length, width, and height of the nanopillars are varied and the output electromagnetic wave is collected by using a field monitor. The magnitude and phase of the output electric field is calculated relative to the input plane wave and is shown in FIG. 2. The left plot of FIG. 2 shows the magnitude of transmitted light as a function of length and width of the nanopillar, when the nanopillar height is 400 nm. Similar plots were generated for nanopillar height of 500 nm, 600 nm, and 700 nm. The right plot shows the magnitude of the phase delay experienced by outgoing light as a function of length and width for nanopillar heights of 500 nm, 600 nm, 700 nm.

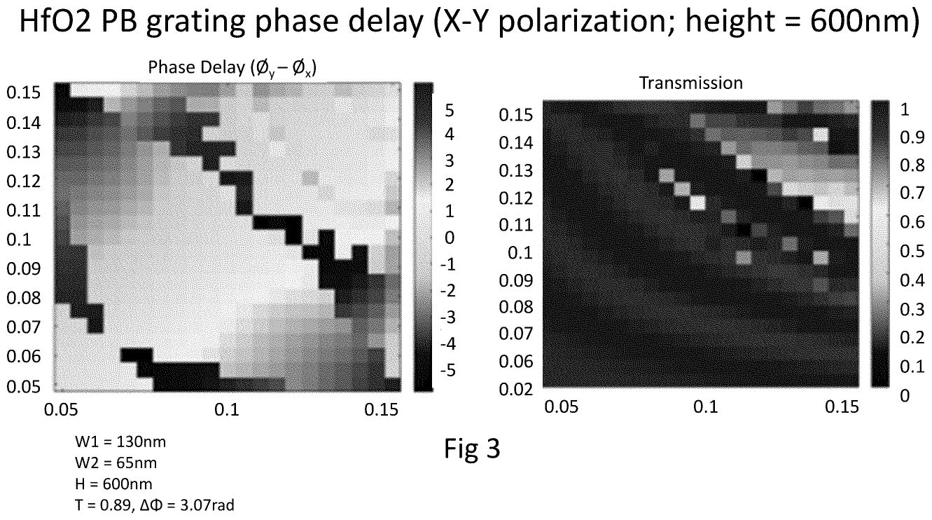

Based on the two simulations for x and y polarized light, we extract the phase retardance and choose a pillar geometry with high transmission and phase retardance value close to π (FIG. 3). In this exemplary embodiments the nanopillars have a rectangular, but can also have a circular, elliptical, or other cross-sections. In this embodiment, the chosen nanopillar dimensions are w1=130 nm, w2=65 nm, and h=600 nm. Thus, in this embodiment the nanopillar aspect ratio of h/w 1 or h/w2 is about 10. The period of the unit cell is 150 nm. FIG. 3 illustrates phase delay (retardance) of the wavefront of light as a function of width and length of nanopillars. The phase delay (retardance) is defined as the difference in phase experienced by an electromagnetic plane wave polarized along x and y direction, wherein propagation axis of the light is along z direction. The right plot of FIG. 3 shows the magnitude of transmitted light for the same embodiment of nanopillars 25 (h=600 nm) as well as dimensions (w1, w2), of the exemplary HfO₂ nanopillars 25 that can generate the required 180° phase delay. FIG. 3 shows that the magnitude T of transmitted light through the nanopillars is 0.89.

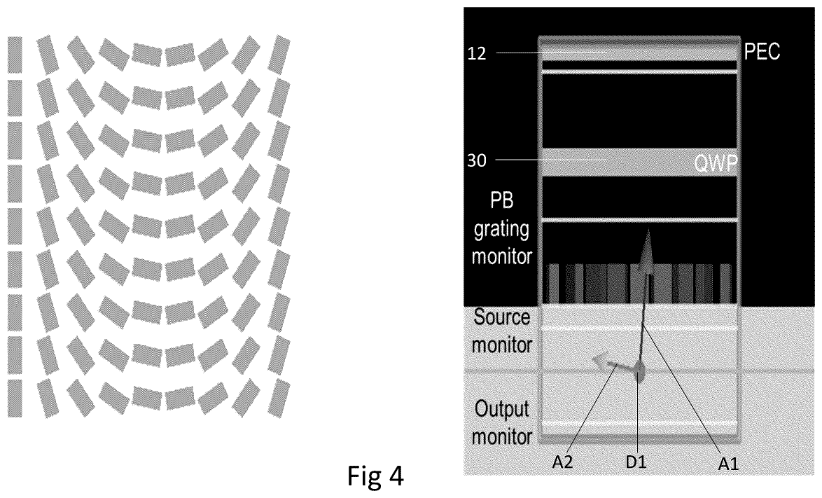

Placement of supercell structure: In order to create the supercell, we need to choose number of unit cells that can sufficiently sample 0 to 2π phase coverage. Based on prior knowledge, we choose 9 nanopillars 25 to sample the 2π phase coverage. Next, we need to determine the rotation angle of each nanopillar. As mentioned above, the rotation angle should be half of the geometric phase assigned to each pillar. Hence, the nanopillars 25 are rotated in incremental steps of 18° from left to right. The total length of the supercell N*ux (where ux is unit cell periodicity) is 1.35 μm. The supercell can be seen in FIG. 4 below. More specifically, the left plot of FIG. 4 shows a top view of the arrangement of the nanopillars 25 in a 9 by 9 grid (9 supercells, each containing a row of unit cells, with one nanopillar per cell), wherein the first pillars (from left) are rotated at 0° along the x axis, the second pillar is rotated at 20°, the third pillar is rotated at 40° and so on. The nanopillars 25 are placed periodically next to each other with a spacing of 150 nm. The right plot shows the cross-sectional view of the simulation settings used for performing the simulation. The arrow A1 denotes the direction along which EM wave is traveling, arrow A2 denotes the direction of the magnetic field, and dot D1 denotes the direction of the electric field. The red pillars are the HfO₂ nanopillars. The rectangle represents the quarter wave plate 30 of 395.8 nm thickness, the rectangle at the top represents the EUV reticle 12 (defined as perfect electric conductor to emulate the reflecting behavior). The thickness d of the quarter wave plate QWP was calculated by the following equation:

$$d = \frac{λ}{4 ( {n}_{e} - {n}_{0} )} = 395.8 \; 33 nm$$

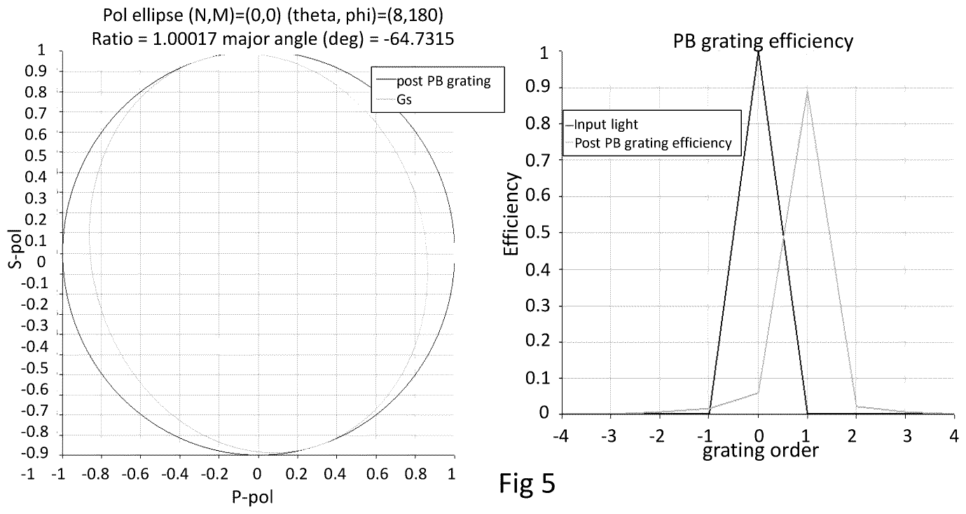

Verification of grating deflection and polarization rotation: Once the simulation has been appropriately setup, we launch LCP light from the bottom and monitor the angle of the outgoing light in the far field. As expected, the light is deflected at angle of 11.36° in air). FIG. 5 below shows the far field projection and the polarization of the incoming and outgoing light and the device efficiency which is close to 90%. The left plot of FIG. 5 shows the polarization of the incoming light reaching the Pancharatnam Berry (PB) grating 20 (blue circle) and polarization of the outgoing light after the exemplary embodiment of the Pancharatnam Berry grating (green circle). The right plot of FIG. 5 shows the diffraction efficiency of the light before and after the grating component 20. The input light is 100% magnitude, and the green output is close to 90% magnitude (i.e., the PB grating efficiency is about 90%).

### Quarter Wave Plate (QWP) 30

Combining the metasurfaces grating 20 with the quarter wave plate 30 allows for circular polarization to linear polarization conversion. Linearly polarized light (indicated by arrows with circles in FIG. 1) is being incident on and reflected from the object that is being tested, for example the object plane OP where the photomask 12 surface under testing is located.

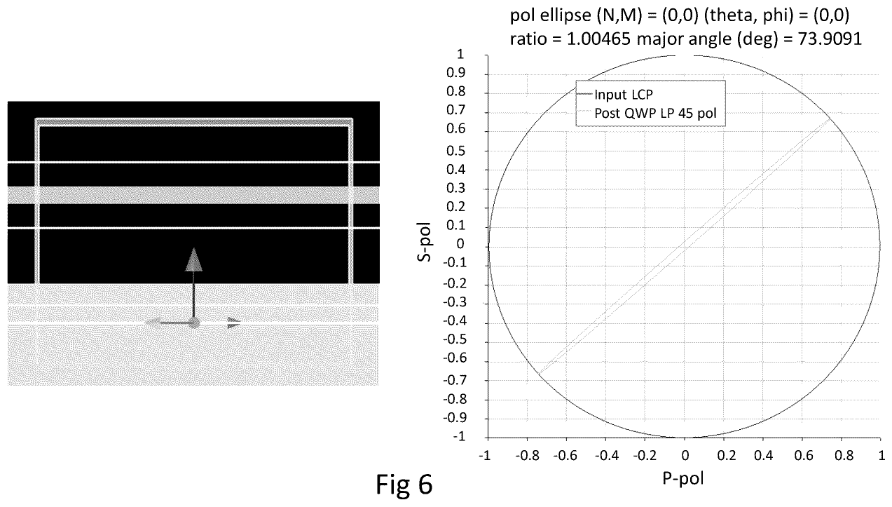

FIG. 6 illustrates results showing polarization before and after exiting a quarter wave plate QWP (LCP→LP45) utilized in inspection device 10 of FIG. 1. QWP 30 converts circularly polarized light into linear polarization and vice versa. Quarter wave plates are made of birefringent materials which have slightly different refractive indices along the two axes perpendicular to propagation direction (commonly referred as slow and fast axis). The QWP 30 adds a phase retardance of π/2 to the light oriented along the slow axis of the crystal relative to the fast axis. Quartz crystal is a commonly used material for QWP operation in DUV region. Other materials such as LiBO₂ (nₑ=1.6768; nₒ=1.5187) can also be utilized. The thickness d of the QWP is determined by the difference in refractive index of the crystal along the two axes given by:

$$Δ ϕ = \frac{2 π ( {n}_{e} - {n}_{0} ) d}{λ} \to \frac{π}{2} = \frac{2 π ( 1.6768 - 1.5187 )}{266 [ nm ]} \to d = 395.8 \; 33 [ nm ] .$$

We verified the operation of the QWP 30 by running a FDTD simulation where we launched RCP light into QWP 30 and monitor the polarization of the outgoing light. As expected, the outgoing light is linearly polarized along 45° to the axis (FIG. 6). M ore specifically, the left plot of FIG. 6 illustrates schematically FDTD simulation, where input light is directed towards the quarter wave plate 30. The yellow horizontal lines show the position of the field monitors used in the simulation. The right plot of FIG. 6 shows the polarization of the light before and after PB grating 20. The input light denoted by blue circle is left circularly polarized light entering the QWP and the green curve is the LP 45 polarization of the output light exiting the QWP 30.

### Full Simulation:

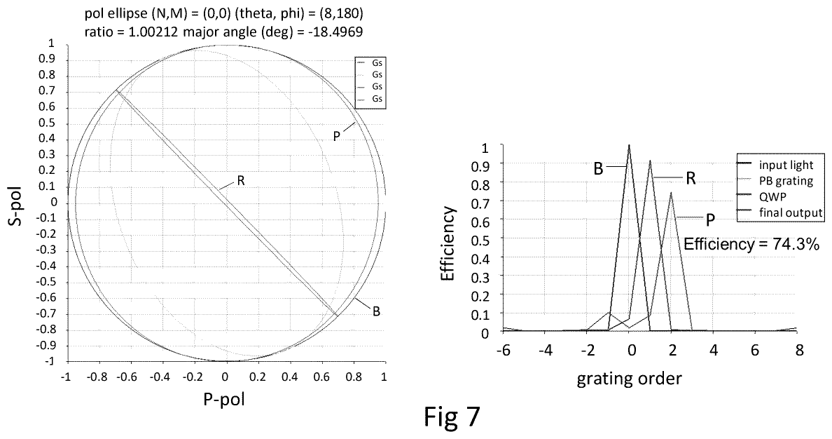

To test the full device operation, we launch LCP light at −7.55° at the PB grating. The outgoing light is RCP which then propagates to the QWP. The QWP rotates the polarization of the light to LP oriented in −45°. The light is then incident on the reticle. Here we have approximated the reticle with a perfectly reflecting mirror. The light is reflected by the reticle and maintains the same polarization as the incident light (LP −45). It then goes through the QWP again which rotates the polarization of the light to RCP (wrt. propagation direction −z). This light is then incident on the PB metagrating which deflects the light at an angle +7.55° and converts it into LCP (wrt. propagation direction −z). Hence the overall separation between the incident and reflected light at PB metagrating is 15.1° while the polarization of the light gets reversed for the incident and outgoing light. The overall efficiency of this exemplary double pass inspection device 10 is about 75%. The polarization of the light and the efficiency of each segment is plotted in FIG. 7.

More specifically, the left plot of FIG. 7 illustrates polarization of the light at different stages: blue curve B is the input light before the grating, the green curve G is the light exiting the PB grating, red curve R is the light exiting the QWP and pink curve P is the light exiting the PB grating after reflection from the EUV photomask. The right plot shows the diffraction efficiency of the device at different stages. The blue curve shows the input light at 100% efficiency. The green and red curves overlaid on top of each other shows the efficiency of the PB grating and QWP. The pink curve shows the efficiency of the final output light after getting reflected from the EUV photomask, QWP, and PB grating in order.

According to exemplary embodiments described herein, the reticle inspection device 10 utilizes a Pancharatnam-Berry phase metasurfaces 20 in conjunction with quarter wave plate 30 in order to split the incident and reflected light while simultaneously rotating the polarization of the light such that linear polarization can be used for inspection of photomasks 12. Based on the simulations done above, we have verified the successful operation of the inspection device 10 and its high efficiency (>70%).

The exemplary inspection device 10 is capable of operating in the deep ultraviolet region (e.g., λ=266 nm). The exemplary inspection device 10 is capable of rotating circularly polarized light into linear polarization and vice versa while splitting the incident and reflected light in opposite directions with high efficiency. The efficiency of the inspection device 10 is at least 70%, for example between 74% and 100%, or between 75 and 100%; and more preferably between 90% and 100%. Other wavelengths of operation, for example, 193 nm, or 213 nm can also be utilized for use with inspection devices 10 described herein. Assuming, for example, the material of unit cells is the same, the height and widths of the nanopillars will change (scale up or down proportional to the wavelength). The periodicity of the unit cell will also be proportional to the wavelength. Furthermore, if the refractive index of the unit nanopillars s changed, the dimensions of the nanopillars and the distances between the nanopillars (periodicity of the unit cells) will also scale proportionally to the change in refractive index of material.

As mentioned above, polarizing beam splitting devices which can split circularly polarized light do not exist commercially. According to at least some of the embodiments described herein, a polarizing beam splitter 18 with a Pancharatnam-Berry metasurface grating (PB metagrating) 20 enables inspection of photomasks with linearly polarized light.

It will be apparent to those skilled in the art that various modifications and variations can be made without departing from the spirit or scope of the invention. Since modifications combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. An inspection device comprising:
(i) a quarter wave plate; and
(ii) a metasurface based polarizing beam splitter situated adjacent to the quarter wave plate.

2. The inspection device of claim 1, further comprising two optical components situated between the object plane and the quarter wave plate.

3. The inspection device of claim 1, further comprising an optical objective lens a zoom lens situated between the object plane and the quarter wave plate.

4. The inspection device of claim 2, further comprising a photomask situated at the object plane.

5. The inspection device of claim 2 further comprising a light source operating at 193, 213 nm, or 266 nm wavelength, and a detector capable of detecting light at 193 nm, 213 nm or 266 nm.

6. The inspection device of claim 5, further comprising: (i) a quarter wave plate situated between the source and the metasurface based polarizing beam splitter and (i) another quarter wave plate situated between the metasurface based polarizing beam splitter and the detector.

7. The inspection device of claim 6, wherein the metasurface based polarizing beam splitter is a Pancharatnam-Berry metasurface grating.
